(19) United States
(12) Patent Application Publication
(10) Pub. No.: US 2007/0080428 A1
(43) Pub. Date: Apr. 12, 2007

(54) Semiconductor film composition

(76) Inventors: Gregory S. Herman, Albany, OR (US); David Punsalan, Eugene, OR (US); Randy Hoffman, Corvallis, OR (US); Jeremy Anderson, Corvallis, OR (US); Douglas Keszler, Corvallis, OR (US); David Blessing, Salem, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/248,819

(22) Filed: Oct. 12, 2005

(51) Int. Cl. H01L 23/58

(52) U.S. Cl. 257/631

(57) ABSTRACT

A semiconductor film composition includes an oxide semiconductor material. At least one polyatomic ion is incorporated into the oxide semiconductor material.

### BACKGROUND

The present disclosure relates generally to film compositions, and more particularly to semiconductor film compositions.

Solution processing may be used to form semiconductor films from precursor solutions. Solution processing may be desirable since, in some instances, it enables certain thin-film deposition processes, including inkjet printing, to be used in manufacturing relatively low-cost electronics. Both organic and inorganic materials may be solution processed.

Generally, organic materials are well suited for the constraints of low temperature processing techniques, including solution-based processing. However, organic materials may provide relatively poor performance, such as inefficient electronic charge transport (i.e., low carrier mobility). Another potential problem with organic electronic materials and devices is that they may have limited stability and/or useful lifetimes.

Inorganic films, such as oxide semiconductors, formed from solution processes may experience undesirable morphological changes (one example of which is cracking) upon crystallization, which may occur when a liquid precursor is converted to the solid film. Further, inorganic films may, in some instances, experience a reduction in charge transport efficiency, (i.e., mobility) due, at least in part, to charged defects at grain boundaries in a poly-crystalline film.

As such, it would be desirable to provide a solution processed inorganic film substantially free from undesirable morphological changes.

### SUMMARY

A semiconductor film composition is disclosed. The composition includes an oxide semiconductor material and at least one polyatomic ion. The polyatomic ion(s) is/are incorporated into the oxide semiconductor material, thereby forming the semiconductor film composition.

### BRIEF DESCRIPTION OF THE DRAWINGS

Features and advantages of the present disclosure will become apparent by reference to the following detailed description and drawings, in which like reference numerals correspond to similar, though not necessarily identical components. For the sake of brevity, reference numerals or features having a previously described function may not necessarily be described in connection with other drawings in which they appear.

FIG. 1 is a flow diagram depicting an embodiment of a method of making an oxide salt semiconductor film;

FIG. 2 is a graph depicting I_{D}-V_{DS} and I_{G}-V_{DS} curves of an embodiment of a thin-film transistor including an oxide salt semiconductor film formed using an embodiment of the method;

FIG. 3 is a graph depicting log(I_{D})-V_{GS} and log(|I_{G}|)-V_{GS} curves of an embodiment of a thin-film transistor including an oxide salt semiconductor film formed using an embodiment of the method;

FIG. 4 is a graph depicting the X-ray diffraction of an indium tin oxide phosphate film formed using an embodiment of the method; and

FIG. 5 is a graph depicting the X-ray diffraction of an indium tin oxide sulfate film formed using an embodiment of the method.

### DETAILED DESCRIPTION

Embodiment(s) of the film disclosed herein incorporate polyatomic ions. In an embodiment, the polyatomic ions are incorporated as metal oxide salt compositions in semiconductor films. As such, the films may advantageously have metal oxide and metal salt entities.

Embodiment(s) of the film may be adapted for use as a variety of electronic devices and/or within a variety of electronic devices. The liquid precursor used to form embodiment(s) of the film may advantageously be polymerized at relatively low processing temperatures. Further, the liquid precursor contains polyatomic ions that may act to substantially inhibit crystallization, thus allowing the formed solid film to retain a substantially amorphous structure across a broad range of processing temperatures. It is to be understood that some embodiments of the film may have some degree of crystallinity without having distinct grains. Without being bound to any theory, it is believed that substantially inhibiting crystallization during film formation advantageously reduces or substantially eliminates undesirable morphological changes in the film. Further, embodiments of the films may substantially avoid potentially dominant grain-boundary-related mobility reductions, and may exhibit higher mobility than that of a poly-crystalline film formed using similar solution-processing methods. Still further, embodiments of the film may have increased stability and useful life as compared to an organic solution-processed film.

Embodiment(s) of the present disclosure form semiconductor film compositions. It is to be understood that, in one or more embodiments as disclosed herein, these semiconductor film compositions may be oxide salt semiconductor films.

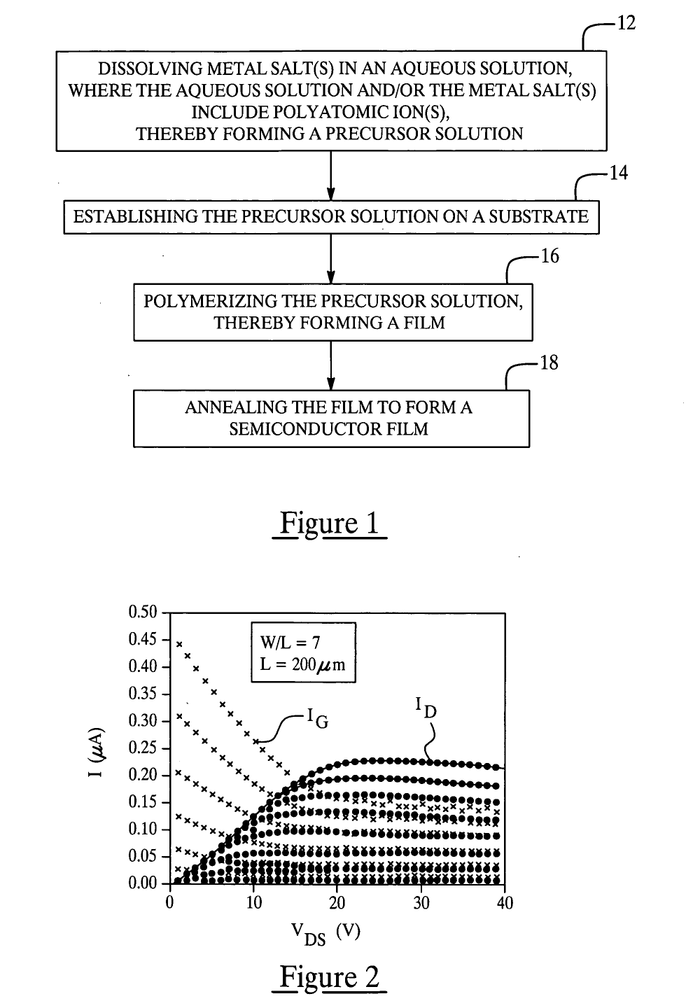

Referring now to FIG. 1, an embodiment of the method of forming an oxide salt semiconductor film is depicted. The method generally includes dissolving metal salt(s) in an aqueous solution to form a precursor solution, where the aqueous solution and/or the metal salt(s) include polyatomic ion(s) (PAI), as shown at reference numeral 12. The precursor solution is established on a substrate, as shown at reference numeral 14. The precursor solution is polymerized, thereby forming a film, as shown at reference numeral 16. The film is then annealed to form the oxide salt semiconductor film, as shown at reference numeral 18.

Embodiments of the film composition as formed by the method(s) disclosed herein include an oxide semiconductor material having the polyatomic ion(s) incorporated into the oxide semiconductor material, thus forming an oxide salt semiconductor film. It is to be understood that the incorporation of the polyatomic ion into the oxide semiconductor results in a semiconductor that may contain metal oxide, metal salt, and polyatomic ion entities.

In an example, a polyatomic anion (PAA) is incorporated into the oxide semiconductor film. Generically, the oxide semiconductor film may be depicted as M_{w}Oₓ, and the oxide salt semiconductor film having the polyatomic anion incorporated therein may be depicted as M_{w}O_{x-y}(PAA)_{2y/z}, where z is the charge on the polyatomic anion. In an embodiment, the polyatomic anion(s) is incorporated as a metal salt in the film. In an embodiment, the polyatomic anion(s) may replace an oxygen group(s) in the film. It is to be understood that the formulas are not necessarily representative of a balanced equation, as the oxide semiconductor salt film incorporating the polyatomic ion is formed from a precursor solution, which may not include the analog (i.e., the semiconductor film not incorporating the polyatomic anion) of the film.

A non-limitative example of the oxide salt semiconductor film is a tin oxide phosphate film having the chemical formula SnO_{1.7}(PO₄)_{0.2}, and its corresponding analog is a tin oxide film having the chemical formula SnO₂. As depicted, the oxide salt semiconductor film is modified from the analog oxide semiconductor in that the polyatomic anion, in this example phosphate from a tin phosphate, is incorporated into the tin oxide analog.

Generally, the charge balance of the oxide salt semiconductor film should be maintained for semiconductors. This may advantageously prevent the formation of excess carriers that may result in a film that is too conductive. In a non-limitative example, it is believed that charge balance may be achieved by substituting, for example, a (SO₄)²⁻ group for an O²⁻ anion.

In general, a polyatomic anion or a polyatomic cation may be incorporated into an anion or a cation entity in the film. A non-limitative example of such an anion incorporation includes a (SO₄)²⁻ group replacing a (SnO₃)²⁻ group, and a non-limitative example of such a cation incorporation includes a S⁶⁺ and an O²⁻ replacing a Sn⁴⁺. In another embodiment, the polyatomic ion may replace a cation and surrounding oxygen group(s).

In an embodiment, the oxide salt semiconductor material includes at least one cation species. Non-limitative examples of the cation species include zinc, cadmium, gallium, indium, germanium, tin, copper, silver, lead, antimony, bismuth, and/or combinations thereof. The cation species in the oxide salt semiconductor material may be supplied from the metal salt(s) used during formation of the film.

It is to be understood that the film may also contain other species (a non-limitative example of which includes hydroxide) depending, at least in part, on the processing conditions.

Referring back to the method of forming the oxide salt semiconductor film, one or more metal salts are added to an aqueous solution to form the precursor solution. The salts may be substantially completely dissolved, and the precursor solution may be heterogeneous, homogeneous, or both heterogeneous in some portions and homogeneous in other portions. It is to be understood that the aqueous solution and/or the metal salts(s) may include the polyatomic ion(s). Non-limitative examples of suitable polyatomic ions include ions of sulfates, borates, phosphates, tungstates, silicates, and/or combinations thereof.

Generally, the aqueous solution includes water, or a mixture of water and an acid. In an embodiment where the aqueous solution includes the polyatomic ions, the aqueous solution may include water and an acid having the polyatomic ion. Examples of acids having polyatomic ion(s) include, but are not limited to phosphoric acid, sulfuric acid, boric acid, tungstic acid, silicic acid, and/or combinations thereof. In this embodiment, the molarity of the acid in the precursor solution ranges from about 0.001 M to about 1.0 M.

In an embodiment where the metal salt, or a mixture of metal salts, includes the polyatomic ion, the metal salt(s) may be dissolved in water. It is to be understood that in this embodiment, a polyatomic ion acid may be added to the precursor solution. The salt component of the metal salt (which metal salt may include the polyatomic ion(s)) includes, but is not limited to sulfate salts, borate salts, phosphate salts, tungstate salts, silicate salts, and/or combinations thereof. Other suitable salt components of the metal salt that may be added to the precursor solution include, but are not limited to iodide salts, bromide salts, chloride salts, perchlorate salts, nitrate salts, acetate salts, formate salts, and/or combinations thereof. The amount of salt in the precursor solution may depend, at least in part, on the film that is to be formed. In one embodiment, the molarity of the salt in the precursor solution ranges from about 0.1 M to about 1.0 M.

After the precursor solution is formed, it may be established on a substrate. Examples of suitable substrate materials include, but are not limited to silicon, quartz, sapphire, glass, metal foils, and various organic substrates, such as polycarbonates (PC), polyarylates (a non-limitative example of which is commercially available under the tradename ARYLITE from Promerus located in Brecksville, Ohio), polyethylene terephthalate (PET), polyestersulfones, polyimides (a non-limitative example of which is commercially available under the tradename KAPTON from DuPont located in Circleville, Ohio), polyolefins, polyethylene naphthalate (PEN), polyethersulfone (PES), polynorbornene (a non-limitative example of which is commercially available under the tradename APPEAR 3000 from Promerus located in Brecksville, Ohio), polyetheretherketone (PEEK), polyetherimide (PEI) (a non-limitative examples of which is commercially available under the tradename ULTEM from General Electric Company, located in Fairfield, Conn.), and/or combinations thereof.

Any suitable deposition technique may be used to establish the precursor solution on the substrate. In an embodiment, the deposition technique is a solution processing technique. Non-limitative examples of such deposition techniques include inkjet printing processes, gravure printing processes, direct write processing, spin-coating processes, spray-coating processes, dip-coating processes, curtain coating processes, and/or the like, and/or combinations thereof.

It is to be understood that the precursor solution may be established on the substrate at any desirable thickness. In an embodiment, the thickness of the established precursor solution may range from about 10 nm to about 1000 nm. The thickness of the final film may range from about 5 nm to about 500 nm, and may be greater than about 500 nm.

In an embodiment, the method further includes polymerizing the precursor solution. Polymerization initiates the formation of chemical bonds in the metal oxide salt semiconductor precursor and assists in the incorporation of the polyatomic ion into the semiconductor material. Polymerization of the precursor solution may be accomplished by any suitable means. In an embodiment, polymerization is accomplished by adding initiators to the precursor solution; exposing the precursor solution to radiation (e.g. ultraviolet radiation); exposing the precursor solution to heat; modifying the constituents in solution by evaporation of the solvent or removal of complexants; and/or combinations thereof. In a non-limitative example embodiment, heating the precursor solution at relatively low temperatures, including temperatures of about 50° C., may initiate polymerization. Heating may be accomplished via a hot plate, furnace, laser, microwave, or the like, or combinations thereof.

In one embodiment, the polymerized film having the polyatomic ion incorporated therein may be established in contact with a second film that generally does not include the polyatomic ion therein. The polyatomic ion(s) may diffuse from the polymerized film into the second film, thereby forming a second film having the polyatomic ions incorporated therein.

The method may further include annealing the polymerized film. Annealing may take place at any suitable temperature. In one embodiment, annealing temperatures may range from about 100° C. to about 600° C., and in another embodiment, annealing temperatures may range from about 250° C. to about 400° C. Annealing the polymerized film results in the formation of the oxide salt semiconductor film having in its composition the polyatomic ion(s) directly incorporated into the semiconductor material. Non-limitative examples of the formed film include tin oxide phosphate, indium tin oxide sulfate, indium tin oxide phosphate, tin oxide sulfate, zinc oxide phosphate, and indium oxide phosphate, and/or the like, and/or combinations thereof.

It is to be understood that annealing of the polymerized film may substantially volatilize excess solvent(s), compounds containing the initial salts and ions, and organic(s) that may be present in the precursor solution or that may be byproducts of the reaction that forms the oxide salt semiconductor film.

Embodiment(s) of the precursor solution are capable of substantially inhibiting crystallization during formation of the oxide salt semiconductor film. As previously stated, this may advantageously substantially eliminate morphological changes (a non-limitative example of which is cracking) in the resulting film. Without being bound to any theory, it is believed the film structure may advantageously increase the suitability of the oxide salt semiconductor film for electronic applications.

It is to be understood that the oxide salt semiconductor film may be incorporated into a variety of electronic devices. In a non-limitative example, the film is operatively disposed in a display device. It is to be further understood that the oxide salt semiconductor film may be adapted for use as a thin-film electronic device, including, but not limited to thin-film transistors and diodes. The oxide salt semiconductor films may also be adapted for use as components in thin-film electronic devices, such as, for example, thin-film transistor channel layers. The precursor solution may be capable of undergoing fabrication processes for forming thin-film electronic devices and/or components thereof.

Still further, the oxide salt semiconductor film may have an electrical conductivity that is adapted to be modulated via the application of an electric field normal to a surface of the oxide film. In a non-limitative example, the electric field normal to the surface of the oxide salt semiconductor film is applied via a gate electrode of a field-effect transistor structure. In an embodiment, a ratio of maximum conductivity of the film to minimum conductivity of the film (as modulated by the gate electrode field) is at least 10, and in another embodiment is at least 10⁴. Such a field-effect transistor may be useful in numerous applications, such as, for example, a voltage-controlled switch or a voltage-controlled current source. A voltage-controlled switch may be used to control a voltage level in an active-matrix display backplane and a voltage-controlled current source may be used to supply a controlled current in an active-matrix display backplane.

To further illustrate embodiment(s) of the present disclosure, the following examples are given. It is to be understood that these examples are provided for illustrative purposes and are not to be construed as limiting the scope of embodiment(s) of the present disclosure.

### EXAMPLE 1

About 40 parts by volume of 0.8 M SnCl₂, about 119 parts by volume of H₂O, and about 1 part by volume of 0.6 M H₃PO₄ were added together to form the precursor solution for a tin oxide phosphate film. The precursor solution was annealed at a temperature of about 500° C. to form the tin oxide phosphate film.

FIG. 2 illustrates the I_{D}-V_{DS} and I_{G}-V_{DS} curves of a thin-film transistor including the tin oxide phosphate film formed in Example 1 as a channel layer. This thin-film transistor is formed on a heavily-doped p-type silicon wafer, the wafer being thermally oxidized to form a gate dielectric layer (100 nm SiO₂). The tin oxide phosphate channel layer is disposed via spin-coating over the gate dielectric. Aluminum source and drain electrodes are deposited by thermal evaporation through a shadow mask.

The curves were measured using a semiconductor parameter analyzer. The drain current, I_{D}, and the gate current, I_{G}, were measured while sweeping the drain-source voltage (V_{DS}) from 0 to 40V at a fixed gate-source voltage (V_{GS}). The gate-source voltage (V_{GS}) was stepped from 0 to 40V in 5V increments. The I_{D}-V_{DS} curve with the largest I_{D} values corresponds to V_{GS}=40 V, the next I_{D}-V_{DS} curve corresponds to V_{GS}=35 V, and so on, as expected for an n-channel field-effect transistor.

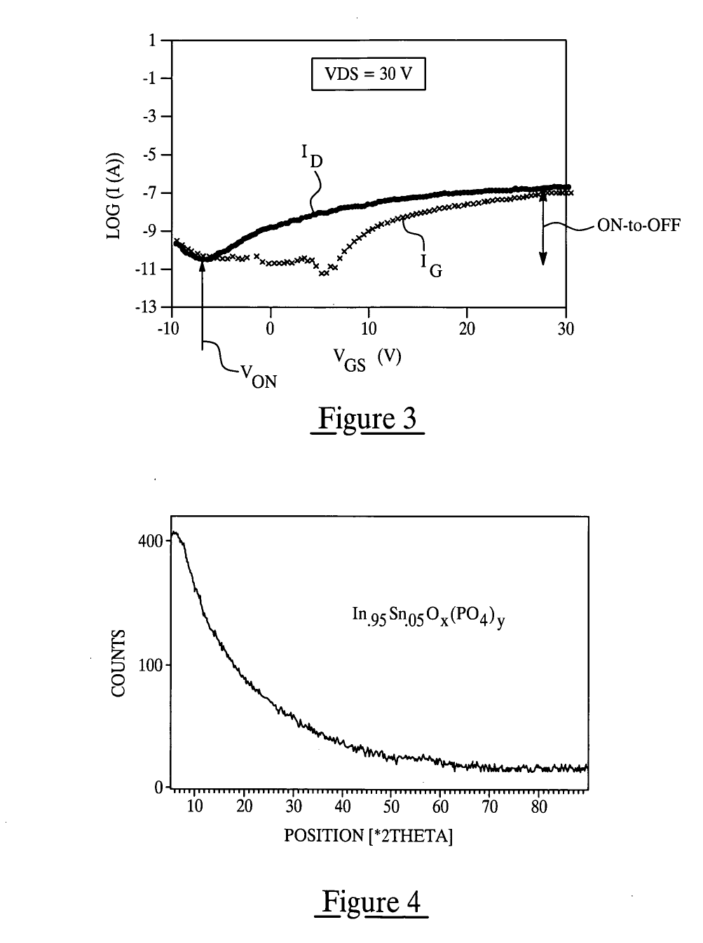

FIG. 3 illustrates the log(I_{D})-V_{GS} and log|I_{G}|-V_{GS} curves of the semiconductor formed in Example 1. The curves were measured using a semiconductor parameter analyzer. A drain-source voltage was held constant at about 30V, while the gate-source voltage was swept from −10 to 30 V. The data reveals an on/off ratio of about 1×10⁴ and a turn on voltage of about −7V. While the mobility extracted from the I_{D} data was relatively low, one can apprehend the viability of the oxide salt semiconductor films.

### EXAMPLE 2

0.38 M In(NO₃)₃.H₂O, 0.02 M SnCl₂.2H₂O, 0.5 M HCl, 0.2 M H₂O₂, and from about 0.15 M to about 1.0 M H₂PO₄ were added together to form the precursor solution for an indium tin oxide phosphate film (In_{.95}Sn_{.05}Oₓ(PO₄)_{y}). The precursor solution was annealed at about 400° C. to form the film. FIG. 4 is a graph of the X-ray diffraction of the formed indium tin oxide phosphate film. As illustrated, the X-ray diffraction shows substantially no indication of a crystalline phase in the film.

### EXAMPLE 3

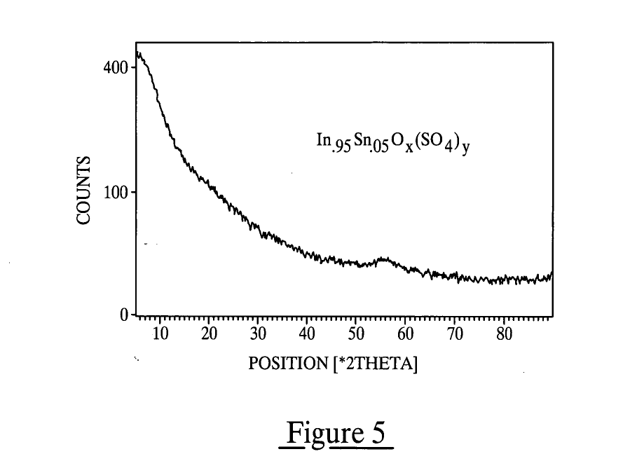

0.38 M In(NO₃)₃.H₂O, 0.02 M SnCl₂.2H₂O, 0.5 M HCl, 0.2 M H₂O₂, and from about 0.15 to about 1.0 M H₂SO₄ were added together to form the precursor solution for an indium tin oxide sulfate film (In_{.95}Sn_{.05}Oₓ(SO₄)_{y}). The precursor solution was annealed at about 400° C. to form the film. FIG. 5 is a graph of the X-ray diffraction of the formed indium tin oxide sulfate film. As illustrated, the X-ray diffraction shows substantially no indication of a crystalline phase in the film.

### EXAMPLE 4

A dielectric, semiconductor, or conductor film is formed so that it has polyatomic ions therein. This film is established in contact with a second film (e.g. a semi-conducting material) that is essentially free of polyatomic ions. The polyatomic ions in the first film may diffuse into the second film, thereby incorporating the polyatomic ions into the second film. The second film may be annealed to form an oxide salt semiconductor having polyatomic ions incorporated therein.

Embodiment(s) of the method and the oxide salt semiconductor film described herein include, but are not limited to the following advantages. Without being bound to any theory, it is believed that the incorporation of the polyatomic ions into the oxide salt semiconductor films may advantageously substantially reduce or eliminate the potential deleterious effects (non-limitative examples of which include film cracking, grain boundary effects, and the like) often seen in other solution processed inorganic oxide semiconductors. As such, embodiments of the film may not have reduced mobility that is often a characteristic of poly-crystalline semiconductor films. Still further, embodiment(s) of the film may have increased stability and useful life when compared to solution processed organic materials.

While several embodiments have been described in detail, it will be apparent to those skilled in the art that the disclosed embodiments may be modified. Therefore, the foregoing description is to be considered exemplary rather than limiting.

What is claimed is:

1. A semiconductor film composition, comprising:
an oxide semiconductor material; and
at least one polyatomic ion incorporated into the oxide semiconductor material.

2. The semiconductor film composition as defined in claim 1 wherein the oxide semiconductor material includes at least one cation species.

3. The semiconductor film composition as defined in claim 2 wherein the at least one cation species is selected from zinc, cadmium, gallium, indium, germanium, tin, copper, silver, lead, antimony, bismuth, and combinations thereof.

4. The semiconductor film composition as defined in claim 1 wherein the at least one polyatomic ion is selected from sulfates, borates, phosphates, tungstates, silicates, and combinations thereof.

5. The semiconductor film composition as defined in claim 1 wherein a liquid precursor of the semiconductor film composition is adapted to substantially inhibit crystallization during processing.

6. The semiconductor film composition as defined in claim 5 wherein the liquid precursor is polymerizable at a temperature of at least about 50° C.

7. The semiconductor film composition as defined in claim 1 wherein the composition is selected from indium tin oxide sulfate, tin oxide phosphate, indium tin oxide phosphate, tin oxide sulfate, zinc oxide phosphate, and indium oxide phosphate.

8. The semiconductor film composition as defined in claim 1 wherein a liquid precursor of the composition is adapted to undergo fabrication processes for forming a thin-film electronic device.

9. The semiconductor film composition as defined in claim 8 wherein the thin-film electronic device is selected from a thin-film transistor and a diode.

10. The semiconductor film composition as defined in claim 1 wherein the semiconductor film has an electrical conductivity adapted to be modulated by application of an electric field normal to a surface of the semiconductor film.

11. The semiconductor film composition as defined in claim 10 wherein a maximum conductivity and a minimum conductivity of the semiconductor film are obtained using electric-field controlled modulation, and wherein a ratio of maximum conductivity to minimum conductivity is at least 10.

12. The semiconductor film composition as defined in claim 1 wherein the polyatomic ion is incorporated as an anion into the oxide semiconductor material.

13. The semiconductor film composition as defined in claim 12 wherein the polyatomic ion substitutionally replaces at least one oxygen anion of an oxide group in the oxide semiconductor material.

14. The semiconductor film composition as defined in claim 1 wherein the polyatomic ion is incorporated as a cation into the oxide semiconductor material.

15. The semiconductor film composition as defined in claim 1 wherein a charge balance of the semiconductor film is obtained via a one-to-one incorporation, a defect migration in a region near a defect, or both.

16. A method of making a semiconductor film, the method comprising:
dissolving at least one metal salt in an aqueous solution, the aqueous solution or the at least one metal salt including at least one polyatomic ion, thereby forming a precursor solution;
establishing the precursor solution on a substrate; and
polymerizing the precursor solution, thereby forming a film having the at least one polyatomic ion incorporated therein.

17. The method as defined in claim 16, further comprising annealing the film, thereby forming the semiconductor film.

18. The method as defined in claim 17 wherein annealing is accomplished by heating the film at a temperature ranging from about 100° C. to about 600° C.

19. The method as defined in claim 17 wherein annealing is accomplished by heating the film at a temperature ranging from about 250° C. to about 400° C.

20. The method as defined in claim 16 wherein the aqueous solution includes water and an acid having the at least one polyatomic ion.

21. The method as defined in claim 20 wherein the acid is selected from phosphoric acid, sulfuric acid, boric acid, tungstic acid, silicic acid, and combinations thereof.

22. The method as defined in claim 16 wherein the at least one metal salt includes the at least one polyatomic ion.

23. The method as defined in claim 22 wherein the at least one polyatomic ion is selected from sulfates, borates, phosphates, tungstates, silicates, and combinations thereof.

24. The method as defined in claim 16 wherein the at least one metal salt includes at least one cation species.

25. The method as defined in claim 24 wherein the at least one cation species is selected from zinc, cadmium, gallium, indium, germanium, tin, copper, silver, lead, antimony, bismuth, and combinations thereof.

26. The method as defined in claim 16 wherein establishing is accomplished by a process selected from inkjet printing processes, gravure printing processes, direct write processing, spin-coating processes, spray-coating processes, dip-coating processes, curtain coating processes, and combinations thereof.

27. The method as defined in claim 16 wherein polymerizing is accomplished by heating the precursor solution at a temperature of about 50° C.

28. The method as defined in claim 16 wherein polymerizing is accomplished by at least one of adding initiators to the precursor solution, exposing the precursor solution to radiation, exposing the precursor solution to heat, removal of solvent, removal of a complexant, or combinations thereof.

29. The method as defined in claim 16 wherein the precursor solution is adapted to substantially inhibit crystallization during polymerization.

30. The method as defined in claim 16 wherein the semiconductor film is adapted for use as a thin-film electronic device.

31. The method as defined in claim 30 wherein the thin-film electronic device is selected from a thin-film transistor and a diode.

32. The method as defined in claim 16 wherein a charge balance of the semiconductor film is obtained via a one-to-one incorporation, a defect migration in a region near a defect, or both.

33. The method as defined in claim 16, further comprising:
establishing the film having the at least one polyatomic ion incorporated therein on a second film without a polyatomic ion therein; and
diffusing the at least one polyatomic ion into the second film.

34. A semiconductor film formed by the method of claim 16.

35. A method of using a semiconductor film, the method comprising operatively disposing the semiconductor film in a display device, the semiconductor film comprising an oxide semiconductor material having at least one polyatomic ion incorporated in the oxide semiconductor material.

36. The method as defined in claim 35 wherein the semiconductor film is operatively disposed in an electronic device that is incorporated into the display device, the electronic device selected from a thin-film transistor and a diode.

37. A method of forming a film having at least one polyatomic ion incorporated therein, the method comprising:
establishing a first film having the at least one polyatomic ion incorporated therein on a second film without a polyatomic ion therein; and
diffusing the at least one polyatomic ion into the second film.

38. The method as defined in claim 37 wherein the film having the at least one polyatomic ion incorporated therein is one of a dielectric film, a semiconductor film, and a conductor film.

39. A semiconductor film, comprising:
an oxide salt semiconductor material; and
means for substantially preventing crystallization of the oxide salt semiconductor material during processing techniques.
